(19) United States
(12) Patent Application Publication
(10) Pub. No.: US 2023/0345798 A1
(43) Pub. Date: Oct. 26, 2023

(54) DISPLAY SUBSTRATE, MANFFACTURING METHOD THEREOF, AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Hongguang YUAN, Beijing (CN); Xiaoliang GUO, Beijing (CN); Zhongfei DONG, Beijing (CN); Zhilong YUAN, Beijing (CN); Donghua JIANG, Beijing (CN); Guobo YANG, Beijing (CN)

(21) Appl. No.: 17/636,147

(22) PCT Filed: Apr. 25, 2021
(86) PCT No.: PCT/CN2021/089609

§ 371 Date: Feb. 17, 2022

(51) Int. Cl. H10K 59/80; H10K 59/131; H10K 59/12

(52) U.S. Cl. CPC H10K 59/873; H10K 59/131; H10K 59/1201

(57) ABSTRACT

A display substrate includes a display region, and the display region includes an open pore region, a first pixel region and an isolation region; the isolation region is located between the first pixel region and the open pore region, the isolation region surrounds the open pore region, and a boundary line between the open pore region and the isolation region is a cutting line; the display substrate further includes: a fracture barrier structure, a peel-off barrier structure and an encapsulation structure, the fracture barrier structure being located in an isolation region, the isolation region including a reserved cutting transition region located between the fracture barrier structure and the open pore region; a peel-off barrier structure being located in the reserved cutting transition region; the distance L between the side of the peel-off barrier structure closest to the open pore region and the cutting line being such that: 0 μm≤L≤30 μm; a first portion of the encapsulation structure being located on a side of the peel-off barrier structure facing away from the base; and the peel-off barrier structure making the surface of the display substrate in contact with the first portion uneven.

### TECHNICAL FIELD

The present disclosure relates to the field of display technology, and more particularly, to a display substrate and manufacturing method thereof and a display device.

### BACKGROUND

With the growing development of display technology, there are more and more active matrix organic light emitting diode (AMOLED) display products with built-in touch screen. At the same time, increasing the percentage of screen of AMOLED display products is more and more concerned. Currently, to achieve higher percentage of screen, an open pore region is typically reserved on the display screen of the display products to accommodate additional components (e. g. cameras, sensors, etc.) included in the display products.

### SUMMARY

It is an object of the present disclosure to provide a display substrate and manufacturing method thereof and display device.

In order to achieve the above object, the present disclosure provides the following technical solutions:

A first aspect of the present disclosure provides a display substrate including a display region, where the display region includes an open pore region, a first pixel region, and an isolation region; the isolation region is located between the first pixel region and the open pore region, the isolation region surrounds the open pore region, and a boundary line between the open pore region and the isolation region is a cutting line; the display substrate further includes:
a fracture barrier structure located at the isolation region, the isolation region including a reserved cutting transition region located between the fracture barrier structure and the open pore region;
a peel-off barrier structure located at the reserved cutting transition region; the distance L between the side of the peel-off barrier structure closest to the open pore region and the cutting line being such that: 0 μm≤L≤30 μm; and
an encapsulation structure, a first portion of the encapsulation structure being located on a side of the peel-off barrier structure facing away from the base; the peel-off barrier structure making the surface of the display substrate in contact with the first portion uneven.

Optionally, the peel-off barrier structure includes at least one of first barrier members, the first barrier member being arranged around the open pore region.

Optionally, an orthographic projection of the cutting line on the base of the display substrate at least partially overlaps an orthographic projection of the first barrier member closest to the open pore region on the base; alternatively, the orthographic projection of the cutting line on the base does not overlap the orthographic projection of the first barrier member closest to the open pore region on the base.

Optionally, the peel-off barrier structure includes a plurality of first barrier members, the plurality of first barrier members being nested in sequence.

Optionally, the distance H2 between the adjacent first barrier members is such that: 10 μm≤H2≤30 μm.

Optionally, the fracture barrier structure includes a plurality of second barrier members, the second barrier members being disposed around the open pore region, the plurality of second barrier members being nested in sequence.

Optionally, the first barrier member and the second barrier member are arranged equidistantly in a direction parallel to the base of the display substrate;
and/or, the arrangement pitch of the first barrier members is greater than the arrangement pitch of the second barrier members in the direction parallel to the base of the display substrate.

Optionally, the first barrier member includes:
a first barrier pattern, a side of the first barrier pattern having a first notch.

Optionally, the first barrier pattern includes a first sub-pattern, a second sub-pattern and a third sub-pattern which are sequentially stacked in a direction away from the base of the display substrate, and in a direction parallel to the base, boundaries of the first sub-pattern and the third sub-pattern each exceed boundaries of the second sub-pattern, and the first notch is formed between the first sub-pattern and the third sub-pattern.

Optionally, the display substrate further includes a thin film transistor located at the first pixel region, the thin film transistor includes a source drain electrode layer, and the source drain electrode layer includes a first conductive layer, a second conductive layer and the third conductive layer which are stacked in sequence along the direction away from the base; the first sub-pattern and the first conductive layer are arranged on the same layer and in the same material, the second sub-pattern and the second conductive layer are arranged on the same layer and in the same material, and the third sub-pattern and the third conductive layer are arranged on the same layer and in the same material; alternatively,
the display substrate further includes a second source drain metal layer located at the first pixel region, and the second source drain metal layer includes a fourth conductive layer, a fifth conductive layer and the sixth conductive layer which are stacked in sequence along the direction away from the base; the first sub-pattern and the fourth conductive layer are arranged on the same layer and in the same material, the second sub-pattern and the fifth conductive layer are arranged on the same layer and in the same material, and the third sub-pattern and the sixth conductive layer are arranged on the same layer and in the same material.

Optionally, at least part of the first barrier member further includes: a second barrier pattern and a third barrier pattern, the second barrier pattern being located between the first barrier pattern and a base of the display substrate, and the third barrier pattern being located between the second barrier pattern and the base.

Optionally, in the same first barrier member, an orthographic projection of the second barrier pattern on the base is located inside an orthographic projection of the third barrier pattern on the base.

Optionally, the display substrate further includes a sub-pixel driving circuit located at the first pixel region, where the sub-pixel driving circuit includes a capacitance structure, the capacitance structure includes a first plate and a second plate arranged opposite to each other, and the first plate is located between the second plate and the base of the display substrate;
the second barrier pattern and the second plate are arranged on the same layer and in the same material; and/or the third barrier pattern and the first plate are provided on the same layer and in the same material.

Optionally, the plurality of the first barrier members are divided into a first portion of the first barrier members and a second portion of the first barrier members, the first portion of the first barrier members being located between the second portion of the first barrier members and the plurality of the second barrier members; where
the first portion of the first barrier members includes the second barrier pattern and a third barrier pattern;
the second portion of the first barrier members does not include the second barrier pattern and the third barrier pattern; and
the second barrier member has the same structure as the first portion of the first barrier member.

Optionally, the display substrate further includes:
a retaining wall structure, the retaining wall structure being arranged on the isolation region, an orthographic projection of the fracture barrier structure on the base of the display substrate being located between an orthographic projection of the retaining wall structure on the base and an orthographic projection of the peel-off barrier structure on the base;
the encapsulation structure extending from the first pixel region to the isolation region, and the encapsulation structure including a first inorganic encapsulation layer, an organic encapsulation layer and a second inorganic encapsulation layer which are stacked in sequence in a direction away from the base; the first inorganic encapsulation layer and the second inorganic encapsulation layer both include the first portion; and the organic encapsulation layer is located on a side of the retaining wall structure away from the open pore region; and
the retaining wall structure including a first retaining wall and a second retaining wall, where the first retaining wall and the second retaining wall are arranged in sequence in a direction close to the open pore region, and a height of the first retaining wall is lower than a height of the second retaining wall in a direction perpendicular to the base.

Optionally, the display substrate further includes:
a planarization layer, a pixel definition layer and a spacer layer which are sequentially stacked and arranged in a direction away from the base, where the planarization layer, the pixel definition layer and the spacer layer are all located at the first pixel region; and
the first retaining wall including a first retaining wall pattern and a second retaining wall pattern which are stacked in sequence in a direction away from the base; where
the first retaining wall pattern and the pixel definition layer are arranged on the same layer and in the same material, and the second retaining wall pattern and the spacer layer are arranged on the same layer and in the same material; or the first retaining wall pattern and the planarization layer are arranged on the same layer and in the same material, and the second retaining wall pattern and the pixel defining layer are arranged on the same layer and in the same material;
the second retaining wall includes a third retaining wall pattern, a fourth retaining wall pattern and a fifth retaining wall pattern which are stacked in sequence in a direction away from the base; the third retaining wall pattern and the planarization layer are arranged on the same layer and in the same material, the fourth retaining wall pattern and the pixel definition layer are arranged on the same layer and in the same material, and the fifth retaining wall pattern and the spacer layer are arranged on the same layer and in the same material.

Optionally, the display substrate further includes:
a plurality of inner isolation posts, where the plurality of inner isolation posts are arranged at the isolation region, the plurality of inner isolation posts are located at one side of the retaining wall structure away from the open pore region, the inner isolation posts surround the open pore region, the plurality of inner isolation posts are nested and arranged in sequence, and a side surface of the inner isolation posts has a second notch; and
a light-emitting functional layer, where the light-emitting functional layer includes a portion located at the first pixel region and a portion of the isolation region, and the portion of the light-emitting functional layer located at the isolation region is interrupted at the side of the inner isolation post.

Optionally, the display substrate further includes a thin film transistor located at the first pixel region, the thin film transistor includes a source drain electrode layer, and the source drain electrode layer includes a first conductive layer, a second conductive layer and the third conductive layer which are stacked in sequence along the direction away from the base; the inner isolation post includes a first isolation pattern, a second isolation pattern and a third isolation pattern which are stacked and arranged in sequence along a direction away from the base, the first isolation pattern and the first conductive layer are arranged on the same layer and in the same material, the second isolation pattern and the second conductive layer are arranged on the same layer and in the same material, and the third isolation pattern and the third conductive layer are arranged on the same layer and in the same material; alternatively,
the display substrate further includes a second source drain metal layer located at the first pixel region, and the second source drain metal layer includes a fourth conductive layer, a fifth conductive layer and the sixth conductive layer which are stacked in sequence along the direction away from the base; the first isolation pattern and the fourth conductive layer are arranged on the same layer and in the same material, the second isolation pattern and the fifth conductive layer are arranged on the same layer and in the same material, and the third isolation pattern and the sixth conductive layer are arranged on the same layer and in the same material.

Based on the technical solution of the display substrate, a second aspect of the present disclosure provides a display device including the above-mentioned display substrate.

Based on the technical solution of a display substrate, a third aspect of the present disclosure provides a method for manufacturing a display substrate, where the display substrate includes a display region, and the display region includes an open pore region, a first pixel region and an isolation region; the isolation region is located between the first pixel region and the open pore region, the isolation region surrounds the open pore region, and a boundary line between the open pore region and the isolation region is a cutting line; the method for manufacturing the display substrate includes:
fabricating a fracture barrier structure located at the isolation region;
fabricating a peel-off barrier structure, the peel-off barrier structure being located at the reserved cutting transition region and the sacrificial cutting transition region; the distance L between the side of the peel-off barrier structure closest to the open pore region and the cutting line being such that: 0 μm≤L≤30 μm; and
fabricating an encapsulation structure, a first portion of the encapsulation structure being located on a side of the peel-off barrier structure facing away from the base; the peel-off barrier structure making the surface of the display substrate in contact with the first portion uneven, where

the step of forming the open pore region and the isolation region includes: cutting the display substrate along the cutting line, the cutting line being a boundary line between the reserved cutting transition region and the sacrificial cutting transition region, and removing all the structures surrounded by the cutting line to form the open pore region.

### BRIEF DESCRIPTION OF THE DRAWINGS

The accompanying drawings, which are included to provide a further understanding of the disclosure and are incorporated in and constitute a part of this disclosure, illustrative embodiment(s) of the present disclosure and the description serve to explain the present disclosure and do not constitute an undue limitation of the present disclosure. In the drawings:

FIG. 1 is a schematic structural diagram of a display substrate provided in embodiments of the present disclosure;

FIG. 2 is a first electron micrograph diagram of the transition region at the lower left corner of a via region provided by embodiments of the present disclosure;

FIG. 3 is a first schematic cross-sectional view taken along the direction N1N2 in FIG. 1;

FIG. 4 is a second schematic cross-sectional view taken along the direction N1N2 in FIG. 1;

FIG. 5 is a schematic view of the two of the first barrier members of FIG. 4;

FIG. 6 is an electron micrograph diagram of the first barrier member of FIG. 4;

FIG. 7 is a third cross-sectional view taken along the direction N1N2 in FIG. 1;

FIG. 8 is a fourth schematic cross-sectional view taken along the direction N1N2 in FIG. 1;

FIG. 9 is a fifth cross-sectional view taken along the direction N1N2 in FIG. 1;

FIG. 10 is a sixth cross-sectional view taken along the direction N1N2 in FIG. 1;

FIG. 11 is a seventh cross-sectional view taken along the direction N1N2 in FIG. 1;

FIG. 12 is an eighth cross-sectional view taken along the direction N1N2 in FIG. 1;

FIG. 13 is a schematic cross-sectional view of two of the first barrier members adjacent to the cutting line of FIG. 2;

FIG. 14 is a second electron micrograph diagram of the transition region at the lower left corner of a via region provided by embodiments of the present disclosure; and

FIG. 15 is a schematic cross-sectional view of two of the first barrier members adjacent to the cutting line in FIG. 14.

### DETAILED DESCRIPTION

In order to further explain the display substrate and the manufacturing method thereof and the display device provided by embodiments of the present disclosure, a detailed description will be given below with reference to the accompanying drawings.

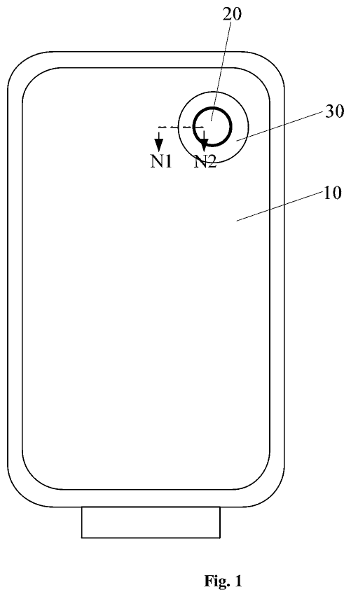

As shown in FIGS. 1, 3 and 9, the present disclosure provides a display substrate including a display region and a peripheral region surrounding the display region. The display region includes an open pore region 20, a first pixel region 10 and an isolation region 30; the isolation region 30 is located between the first pixel region 10 and the open pore region 20, and the isolation region 30 surrounds the open pore region 20. The isolation region 30 includes a reserved cutting transition region 301 adjacent to the open pore region 20, and the minimum width of the reserved cutting transition region 301 in a direction parallel to the base 60 includes 50 microns. The reserved cutting transition region 301 is arranged only with an organic layer and an inorganic layer which are stacked in sequence, and the organic layer and the inorganic layer are both formed simultaneously with the corresponding film layer in the first pixel region 10. The display substrate is bonded to the cover plate by an adhesive.

The process flow of the manufacturing the above-mentioned display substrate includes: forming a corresponding functional structure on the base 60, then performing a punching process to form the open pore region 20, then removing the protective film provided on one side of the adhesive, bonding one side of the adhesive removing the protective film to the surface of the display substrate where the functional structure is formed, then removing the protective film on the other side of the adhesive, bonding one side of the adhesive facing away from the display substrate to the cover plate.

Since the reserved cutting transition region 301 is located at the periphery of the open pore region 20, and the reserved cutting transition region 301 does not include a functional structure, and the surface thereof is relatively flat, so that the adhesion between the encapsulation structure 65 located at the reserved cutting transition region 301 in the display substrate and the film layer therebelow is poor, and thus in the process of removing the protective film on the other side of the adhesive, the encapsulation structure 65 located at the reserved cutting transition region 301 is easily peeled off, resulting in poor reliability of the display substrate.

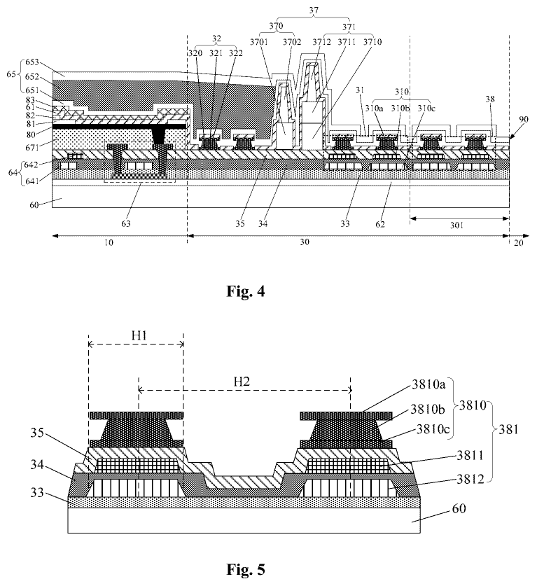

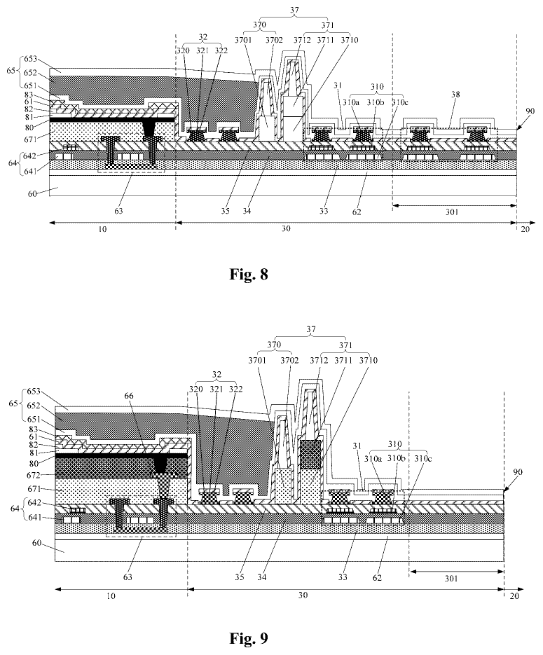

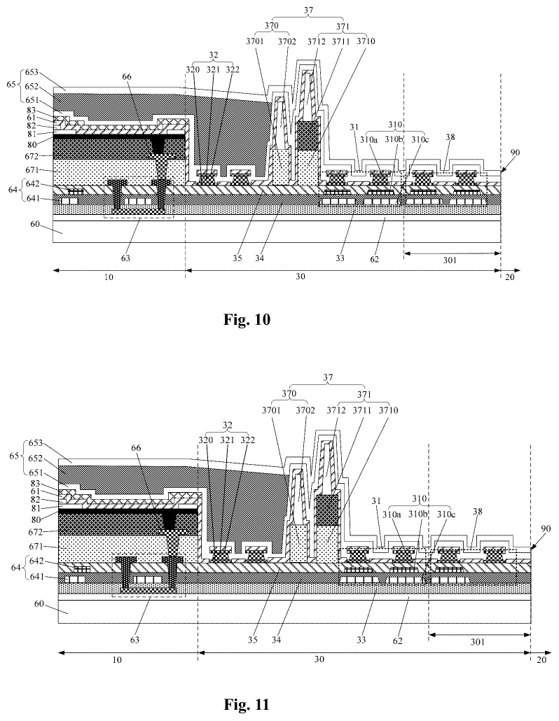

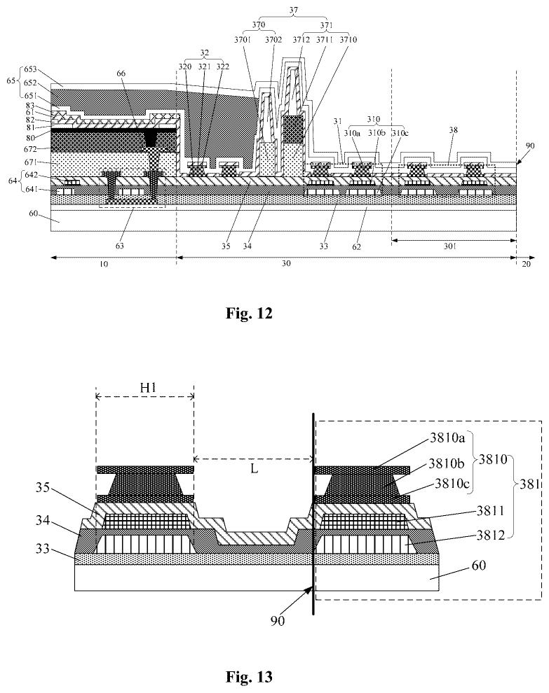

Based on the above-mentioned problem, with reference to FIGS. 4, 7, 8 and 10-12, embodiments of the present disclosure provides a display substrate, including a display region, the display region including an open pore region 20, a first pixel region 10 and an isolation region 30; the isolation region 30 is located between the first pixel region 10 and the open pore region 20, the isolation region 30 surrounds the open pore region 20, and a boundary line between the open pore region 20 and the isolation region 30 is a cutting line 90; the display substrate further includes:
a fracture barrier structure 31 located at the isolation region 30, where the isolation region 30 includes a reserved cutting transition region 301 located between the fracture barrier structure 31 and the open pore region 20;
a peel-off barrier structure 38 located at the reserved cutting transition region 301; where the distance L between the side of the peel-off barrier structure 38 closest to the open pore region and the cutting line 90 is such that: 0 μm≤L≤30 μm; and
an encapsulation structure 65, where a first part of the encapsulation structure 65 is located on a side of the peel-off barrier structure 38 facing away from the base 60; the peel-off barrier structure 38 makes the surface of the display substrate in contact with the first portion uneven.

Illustratively, the display substrate has a display region and a peripheral region surrounding the display region, the display region including a first pixel region 10, an open pore region 20, and an isolation region 30 located between the first pixel region 10 and the open pore region 20. The isolation region 30 is arranged around the open pore region 20, and the first pixel region 10 is arranged around the isolation region 30.

Illustratively, the display substrate includes a rectangular display region, the open pore region 20 is located at the upper left corner, the upper middle corner or the upper right corner of the rectangular display region, and the specific location and shape of the open pore region 20 are not particularly required. Illustratively, the shape of the open pore region 20 includes: circular or rectangular shapes.

The isolation region 30 is provided with an inorganic layer structure located on the base 60; the inorganic layer structure includes a plurality of inorganic film layers arranged in a stacked manner; each inorganic film layer is formed as an integral structure with a corresponding inorganic film layer (such as a first gate insulation layer 33, a second gate insulation layer 34, an inter-layer insulation layer 35, etc.) in the first pixel region 10; and the inorganic film layer can function as an insulation layer in the first pixel region 10. The inorganic film layer has poor flexibility, and when the opening hole region 20 is cut and formed, the inorganic film layer at the cutting line 90 is easy to have a brittle fracture, and the crack easily takes the inorganic film layer as a channel and further extends to the first pixel region 10, so as to affect the yield of the display substrate.

Illustratively, the fracture barrier structure 31 surrounds the open pore region 20. The fracture barrier structure 31 is capable of spacing adjacent inorganic film layers so that contact stacking of multiple inorganic film layers can be avoided, blocking the path of the crack extending to the first pixel region 10.

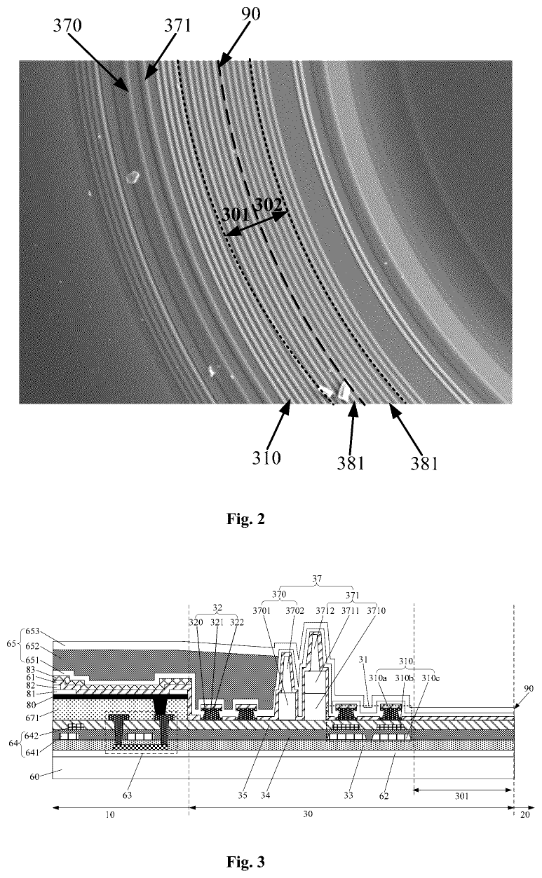

Illustratively, as shown in FIG. 2, the reserved cutting transition region 301 is disposed around the open pore region 20. It needs to be noted that the display substrate includes a cutting transition region (such as a region corresponding to a double-headed arrow in FIG. 2) before forming the open pore region 20, the cutting transition region includes a reserved cutting transition region 301 and a sacrificial cutting transition region 302, the reserved cutting transition region 301 has the same structure as the sacrificial cutting transition region 302, and both the reserved cutting transition region 301 and the sacrificial cutting transition region 302 form the peel-off barrier structure 38.

The reserved cutting transition region 301 and the sacrificial cutting transition region 302 are divided by a cutting line 90 along which a structure included by the reserved cutting transition region 301 reserves and a structure included by the sacrificial cutting transition region 302 is removed to form the open pore region 20. Since the specific position of the cutting line 90 is selected at the cutting transition region, and the cutting transition region is provided with the peel-off barrier structure 38 as a whole, no matter where the cutting line 90 is specifically selected at the cutting transition region, the peel-off barrier structure 38 can be ensured to be provided on the reserved cutting transition region 301 after cutting, and the peel-off barrier structure 38 can make the surface of the display substrate in contact with the first portion uneven, increasing the contact area between the first portion and the film layer in contact therewith; the adhesion between the first part and the underlying film layer is thus well enhanced, reducing the risk of peeling off the first part from the display substrate.

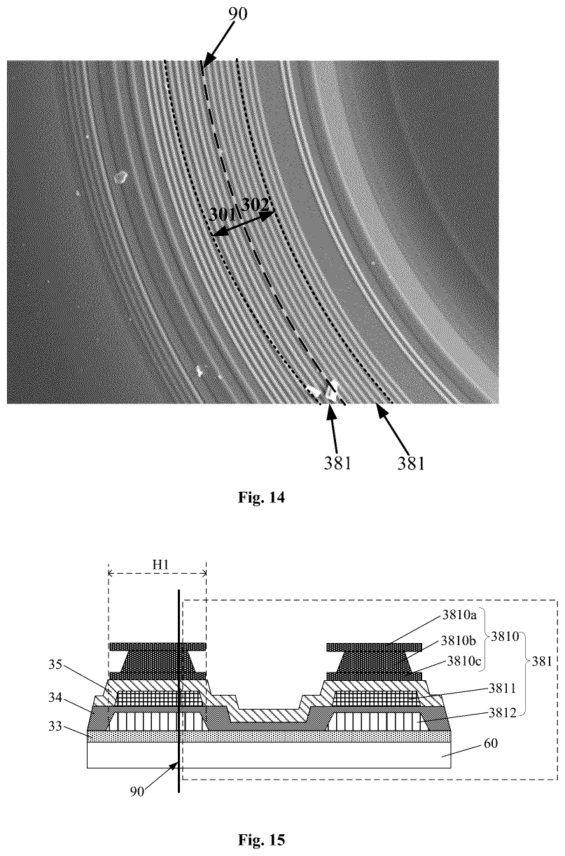

Illustratively, the distance L between the side of the peel-off barrier structure 38 closest to the open pore region and the cutting line 90 is such that: 0 μm≤L≤30 μm. As shown in FIGS. 14 and 15, when the orthographic projection of the side of the peel-off barrier structure 38 closest to the open pore region on the base of the display substrate overlaps with the orthographic projection of the cutting line 90 on the base of the display substrate, L is Ow. As shown in FIGS. 2 and 13, when the orthographic projection of the side of the peel-off barrier structure 38 closest to the open pore region on the base of the display substrate does not overlap the orthographic projection of the cutting line 90 on the base of the display substrate, L satisfies: 0 μm≤L≤30 μm.

Illustratively, the distance L between the side of the peel-off barrier structure 38 closest to the open pore region and the cutting line 90 is such that: 0 μm≤L≤25 μm.

Illustratively, the distance between the side of the peel-off barrier structure 38 closest to the open pore region and the cutting line 90 includes: the distance between the orthographic projection of the side of the peel-off barrier structure 38 closest to the open pore region on the base and the orthographic projection of the cutting line 90 on the base of the display substrate.

At least a portion of the encapsulation structure 65 can cover the entire region of the display substrate, and the encapsulation structure 65 can effectively block the intrusion of external moisture and oxygen into the interior of the display substrate, which is advantageous for extending the service life of the display substrate.

According to the above-mentioned specific structure of the display substrate, it can be seen that in the display substrate provided by the embodiments of the present disclosure, by providing the fracture barrier structure 31 in the isolation region 30, the crack located near the open pore region 20 is effectively blocked from extending to the inside of the first pixel region 10. At the same time, by providing the peel-off barrier structure 38 at the reserved cutting transition region 301, the adhesion between the first portion and the underlying film layer is enhanced, the risk of peeling off the first portion from the display substrate is reduced, and the yield of reliability of the display substrate is ensured.

It needs to be noted that the display substrate provided by the embodiments of the present disclosure can be used not only in an OLED, but also in a display product such as a quantum dot.

As shown in FIGS. 4-12, in some embodiments, the peel-off barrier structure 38 includes at least one of first barrier members 381 arranged around the open pore region 20.

Illustratively, the peel-off barrier structure 38 includes one or more first barrier members 381, where one of the first barrier members 381 is included, the one of first barrier members 381 should be as close as possible to the boundary of the open pore region 20, i.e., the cutting line 90; a plurality of the first barrier members 381 are included, the plurality of the first barrier members 381 may be sequentially spaced apart in a direction away from the open pore region 20.

Illustratively, the first barrier members 381 can form a step difference to make the surface of the display substrate in contact with the first portion uneven.

The above-described arrangement of the first barrier members 381 around the open pore region 20 enables good adhesion of the first portion to the underlying film layer at various locations around the open pore region 20, thereby better reducing the risk of peeling off the first portion from the display substrate and ensuring the yield of reliability of the display substrate.

In some embodiments, as shown in FIGS. 14 and 15, the orthographic projection of the cutting line 90 on the base 60 of the display substrate overlaps, at least in part, the orthographic projection of the first barrier member 381 closest to the open pore region 20 on the base 60; alternatively, as shown in FIGS. 2 and 13, the orthographic projection of the cutting line 90 on the base 60 does not overlap the orthographic projection of the first barrier member 381 on the base 60 closest to the open pore region 20.

As shown in FIGS. 2 and 13, illustratively, when cutting along the cutting line 90, the cutting line 90 may be positioned between two adjacent first barrier members 381, i.e., the orthographic projection of the cutting line 90 on the base 60 does not overlap the orthographic projection of the first barrier members 381 on the base 60 closest to the open pore region 20.

As shown in FIGS. 14 and 15, illustratively, the cutting line 90 may fall on a certain first barrier member 381, i.e., when cutting along the cutting line 90, the first barrier members 381 are divided into two portions, one of which is subsequently removed.

It needs to be noted that the portion enclosed by the dotted line in FIG. 13 and FIG. 15 is a portion to be subsequently removed, and the portion is positioned to subsequently form the open pore region 20.

As shown in FIGS. 4-12, in some embodiments, the peel-off barrier structure 38 includes a plurality of first barrier members 381 nested in sequence.

Illustratively, the number of the first barrier members 381 is between one and ten.

Illustratively, the peel-off barrier structure 38 includes a plurality of first barrier members 381, each first barrier member 381 disposed around the open pore region 20, each orthographic projection of a first barrier member 381 on the base 60 being capable of being surrounded by an adjacent orthographic projection of the first barrier member 381 on the base 60 in a direction of the open pore region 20 toward the isolation region 30.

This arrangement further enhances the adhesion of the first portion to the underlying film layer at various locations around the open pore region 20, thereby better reducing the risk of peeling off the first portion from the display substrate and ensuring a yield of reliability of the display substrate.

As shown in FIG. 5, in some embodiments, the distance H2 between the adjacent first barrier members is such that: 10 μm≤H2≤30 μm.

Illustratively, the minimum distance between adjacent orthographic projections of the first barrier members 381 on the base 60 of the display substrate includes 10 microns.

Illustratively, the distance between adjacent ones of the first barrier members 381 in a direction parallel to the base 60 of the display substrate includes: 12 microns, 14 microns, 28 microns, 30 microns.

Illustratively, as shown in FIG. 5, H1 is the width of the first barrier member 381. Illustratively, the width of the first barrier member 381 is: the width of the third sub-graph 3810a included in the first barrier pattern 3810 in the first barrier member 381. Illustratively, the first barrier pattern 3810 includes a third sub-pattern 3810a having the same width as the first sub-pattern 3810c. Exemplary values for H1 include, but are not limited to, 4.8 microns.

Illustratively, as shown in FIG. 5, H2 is the distance between adjacent first barrier members 381.

Illustratively, the distance between adjacent first barrier members 381 is: the distance between the center-lines of the orthographic projections of adjacent first barrier members 381 on the base 60. Illustratively, the center-line is located at the location of the projection on the base 60 of the left and right longitudinally extending dashed lines corresponding to H2 in FIG. 5.

As shown in FIGS. 3, 4, and 7-12, in some embodiments, the fracture barrier structure 31 includes a plurality of second barrier members 310 disposed around the open pore region 20, the plurality of second barrier members 310 being nested in sequence.

Illustratively, the fracture barrier structure 31 includes one or more second barrier members 310. When one of the second barrier members 310 is provided, the second barrier member 310 should be as close as possible to the open pore region 20, and when a plurality of the second barrier members 310 are provided, a plurality of the second barrier members 310 may be sequentially spaced apart in a direction away from the open pore region 20.

It needs to be noted that the number of the second barrier members 310, the size of the second barrier members 310, and the distance between adjacent second barrier members 310 can be adjusted according to actual needs, process conditions and effects. Illustratively, the number of the second barrier members 310 is between one and ten, and the distance between adjacent second barrier members 310 may be selected to be tens of micrometers. Illustratively, the distance between adjacent second barrier members 310 is the same as the distance between adjacent first barrier members 381 described above.

The plurality of second barrier members 310 can space the inorganic film layers adjacent in the direction perpendicular to the base 60 so that contact stacking of the inorganic film layers can be avoided, blocking the path of the crack extending toward the first pixel region 10.

As shown in FIGS. 4 to 7, 10 and 11, in some embodiments, the first barrier member 381 and the second barrier member 310 are equally spaced in a direction parallel to the base 60 of the display substrate.

Illustratively, the display substrate includes the first barrier member 381 and the second barrier member 310, which can be equally spaced at a minimum distance. Illustratively, the minimum distance includes a minimum distance achievable by the fabrication process.

Illustratively, adjacent ones of the first barrier members 381 have a first pitch therebetween, adjacent ones of the second barrier members 310 have a first pitch therebetween, and adjacent ones of the first barrier members 381 and the second barrier members 310 have a first pitch therebetween.

The above-mentioned arrangement that the first barrier member 381 and the second barrier member 310 are arranged at equal intervals enables the first barrier member 381 and the second barrier member 310 to be uniformly arranged in the area where the isolation region 30 is close to the via region, so that not only the extension of cracks to the first pixel region 10 is better avoided, but also the adhesive property of the encapsulation structure 65 and the underlying film layer is better ensured.

As shown in FIGS. 5, 6, 8 and 12, in some embodiments, the arrangement pitch of the first barrier members 381 is greater than the arrangement pitch of the second barrier members 310 in a direction parallel to the base 60 of the display substrate.

Illustratively, adjacent ones of the first barrier members 381 have a second spacing therebetween, adjacent ones of the second barrier members 310 have a first spacing therebetween, and adjacent ones of the first barrier members 381 and the second barrier members 310 have a second spacing therebetween. Illustratively, the second pitch is greater than the first pitch.

The above-mentioned arrangement pitch of the first barrier members 381 is greater than the arrangement pitch of the second barrier members 310, so that the manufacturing cost of the display substrate can be better saved while avoiding the extension of cracks to the first pixel region 10 and ensuring the adhesive property of the encapsulation structure 65 and the underlying film layer.

As shown in FIGS. 5 and 6, in some embodiments, the first barrier member 381 includes a first barrier pattern 3810 having a first notch on a side of the first barrier pattern 3810.

Illustratively, the encapsulation structure 65 includes a first portion capable of contacting a portion of the first barrier pattern 3810 located in the first notch.

Illustratively, the display substrate further includes a light emitting functional layer 61, the light emitting functional layer 61 being capable of extending from the first pixel region 10 to the isolation region 30, the light emitting functional layer 61 being capable of breaking at a first notch of the first barrier pattern 3810.

The above-described arrangement of the first barrier member 381 including the first barrier pattern 3810 effectively increases the contact area between the first portion and the underlying film layer, further improving the adhesion between the first portion and the underlying film layer. Furthermore, the light-emitting functional layer 61 can be broken at the first notch of the first barrier pattern 3810 to better block intrusion of moisture and oxygen to the first pixel region 10 by using the light-emitting functional layer 61 as a transmission path.

As shown in FIGS. 5 and 6, in some embodiments, the first barrier pattern 3810 includes a first sub-pattern 3810c, a second sub-pattern 3810b, and a third sub-pattern 3810a sequentially stacked in a direction away from the base 60 of the display substrate, boundaries of the first sub-pattern 3810c and the third sub-pattern 3810a each exceed boundaries of the second sub-pattern 3810b in a direction parallel to the base 60, and the first notch is formed between the first sub-pattern 3810c and the third sub-pattern 3810a.

Illustratively, the materials of the first sub-pattern 3810c and the third sub-pattern 3810a are the same, the materials of the first sub-pattern 3810c and the second sub-pattern 3810b are different, and under the same etching condition, the etching rate of the second sub-pattern 3810b is greater than the etching rate of the first sub-pattern 3810c and the third sub-pattern 3810a.

Illustratively, the first sub-pattern 3810c and the third sub-pattern 3810a are made of metal Ti, and the second sub-pattern 3810b is made of metal Al. Illustratively, the fabrication of the first barrier pattern 3810 includes: forming a Ti metal layer, an Al metal layer, a Ti metal layer and a photoresist layer which are sequentially stacked and arranged in a direction away from the base 60; exposing the photoresist layer to form a photoresist removal region and a photoresist reserved region, wherein the photoresist retention region corresponds to the region where the first barrier pattern 3810 is located, and the photoresist removal region corresponds to other regions except the region where the first barrier pattern 3810 is located; etching a Ti metal layer, an Al metal layer and a Ti metal layer which are arranged on top of each other by using the photoresist of the photoresist reserved area as a mask; and since the etching rate of the Al metal layer is greater than the etching rate of the Ti metal layer, the first notch can be formed between the first sub-pattern 3810c and the third sub-pattern 3810a.

The above-mentioned arrangement of the first barrier pattern 3810 including the first sub-pattern 3810c, the second sub-pattern 3810b and the third sub-pattern 3810a enables the first barrier pattern 3810 to be formed in a single patterning process, greatly simplifying the manufacturing process of the display substrate and reducing the manufacturing cost of the display substrate.

As shown in FIGS. 4, 7 and 8, in some embodiments, the display substrate further includes a thin film transistor 63 located at the first pixel region 10, the thin film transistor 63 includes a source drain electrode layer, and the source drain electrode layer includes a first conductive layer, a second conductive layer and the third conductive layer which are stacked in sequence in a direction away from the base 60.

The first sub-pattern 3810c and the first conductive layer are disposed on the same layer and in the same material, the second sub-pattern 3810b and the second conductive lay are disposed on the same layer and in the same material, and the third sub-pattern 3810a and the third conductive layer are disposed on the same layer and in the same material.

Illustratively, the first pixel region 10 includes a sub-pixel driving circuit, the sub-pixel driving circuit includes the thin film transistor 63, a source drain electrode layer of the thin film transistor 63 is made of a first source drain metal layer, and the source drain electrode layer includes a source electrode and a drain electrode.

Illustratively, the first conductive layer and the third conductive layer are made of metal Ti, and the second conductive layer is made of metal Al. The source drain electrode layer is formed in the same manner as the first barrier pattern 3810 and will not be described in detail herein.

The source drain electrode layer and the first barrier pattern 3810 can be formed simultaneously in the same patterning process, which effectively simplifies the manufacturing process of the display substrate and reduces the manufacturing cost of the display substrate.

As shown in FIGS. 9-12, in some embodiments, the display substrate further includes a second source drain metal layer 66 located at the first pixel region 10, and the second source drain metal layer 66 includes a fourth conductive layer, a fifth conductive layer and the sixth conductive layer which are stacked in sequence in a direction away from the base 60.

The first sub-pattern 3810c and the fourth conductive layer are arranged on the same layer and in the same material, the second sub-pattern 3810b and the fifth conductive layer are arranged on the same layer and in the same material, and the third sub-pattern 3810a and the sixth conductive layer are arranged on the same layer and in the same material.

Illustratively, the display substrate includes an active layer, a first gate insulating layer 33, a first gate metal layer, a second gate insulating layer 34, a second gate metal layer, an inter-layer insulating layer 35, a first source and drain metal layer, a first planarization layer 671, a second source and drain metal layer 66, a second planarization layer 672, an anode layer 80, a pixel defining layer 81, a light emitting functional layer 61, a cathode layer 83, a first inorganic encapsulation layer 651, an organic encapsulation layer 652 and a second inorganic encapsulation layer 653 which are stacked in sequence in a direction away from the base 60.

Illustratively, the display substrate further includes a flexible layer between the active layer and the base 60, the flexible layer including: A first polyimide layer, a first isolation layer, a second polyimide layer, a second isolation layer and a buffer layer 62 which are arranged in a stack. The first isolation layer is made of silicon nitride, and the second isolation layer is made of silicon oxide.

Illustratively, the insulating layer in the display substrate includes an inorganic insulating layer made of silicon nitride and/or silicon oxide material.

Illustratively, the second source drain metal layer is used to form some conductive connections, and may also be used to form some signal lines, etc.

Illustratively, the fourth conductive layer and the sixth conductive layer are made of metal Ti, and the fifth conductive layer is made of metal Al.

The second source drain metal layer 66 and the first barrier pattern 3810 can be formed simultaneously in the same patterning process, which effectively simplifies the manufacturing flow of the display substrate and reduces the manufacturing cost of the display substrate.

As shown in FIGS. 5 and 6, in some embodiments, at least a portion of the first barrier member 381 further includes: a second barrier pattern 3811 located between the first barrier pattern 3810 and the base 60 of the display substrate, and a third barrier pattern 3812 located between the second barrier pattern 3811 and the base 60.

Illustratively, an insulating layer is provided between the first barrier pattern 3810 and the second barrier pattern 3811, and an insulating layer is provided between the second barrier pattern 3811 and the third barrier pattern 3812.

The above-mentioned first barrier member 381 further includes the second barrier pattern 3811 and the third barrier pattern 3812, so that the second barrier pattern 3811 and the third barrier pattern 3812 can space the second gate insulating layer 34 and the inter-layer insulating layer 35 apart, and prevent cracks from directly extending to a display region along the second gate insulating layer 34 and the inter-layer insulating layer 35 with the stacked second gate insulating layer 34 and the inter-layer insulating layer 35 as a transmission path.

The above-mentioned arrangement of the first barrier member 381 further includes the second barrier pattern 3811 and the third barrier pattern 3812, which increases the step height generated by the first barrier member 381 as a whole, facilitates to increase the contact area between the first portion and the film layer below it, and reduces the risk of the first portion separating from the film layer below it. Furthermore, after increasing the step height generated by the first barrier member 381 as a whole, the depth of the recessed structure between the adjacent first barrier members 381 is increased, which is advantageous in improving the encapsulation effect of the display substrate.

It needs to be noted that in FIGS. 3, 4 and 7-12, the surfaces of the second gate insulating layer 34 and the inter-layer insulating layer 35 facing away from the base 60 are uneven. The surface of the second gate insulating layer 34 and the inter-layer insulating layer 35 facing away from the base 60 will continue the appearance of the segment difference covered thereby, so that the surface of the second gate insulating layer 34 and the inter-layer insulating layer 35 facing away from the base 60 also has the segment difference.

As shown in FIG. 5, in some embodiments, disposed in the same first barrier member 381, the orthographic projection of the second barrier pattern 3811 on the base 60 is located inside the orthographic projection of the third barrier pattern 3812 on the base 60.

The above-mentioned arrangement enables the second barrier pattern 3811 and the third barrier pattern 3812 to be integrally formed in a trapezoid-like structure, which is advantageous in increasing the contact area between the first portion and the film layer below it, and reducing the risk of the first portion separating from the film layer below it.

As shown in FIGS. 4 and 7-12, in some embodiments, the display substrate further includes a sub-pixel driving circuit located at the first pixel region 10, the sub-pixel driving circuit includes a capacitance structure 64, the capacitance structure 64 includes a first plate 641 and a second plate 642 arranged opposite to each other, the first plate 641 is located between the second plate 642 and a base 60 of the display substrate.

The second barrier pattern 3811 and the second plate 642 are provided on the same layer and in the same material; and/or, the third barrier pattern 3812 and the first plate 641 are disposed on the same layer and in the same material.

Illustratively, the first gate metal layer includes the first plate 641 and the second gate metal layer includes the second plate 642. Illustratively, the first plate 641 and the second plate 642 are made of metallic molybdenum.

The above-mentioned second barrier pattern 3811 and the second plate 642 are provided on the same layer and the same material, so that the second barrier pattern 3811 and the second plate 642 can be formed simultaneously in the same patterning process, which is beneficial to simplify the manufacturing process flow of the display substrate and reduce the manufacturing cost of the display substrate.

The above-mentioned third barrier pattern 3812 and the first plate 641 are provided on the same layer and in the same material, so that the third barrier pattern 3812 and the first plate 641 can be formed simultaneously in the same patterning process, which is beneficial to simplify the manufacturing process flow of the display substrate and reduce the manufacturing cost of the display substrate.

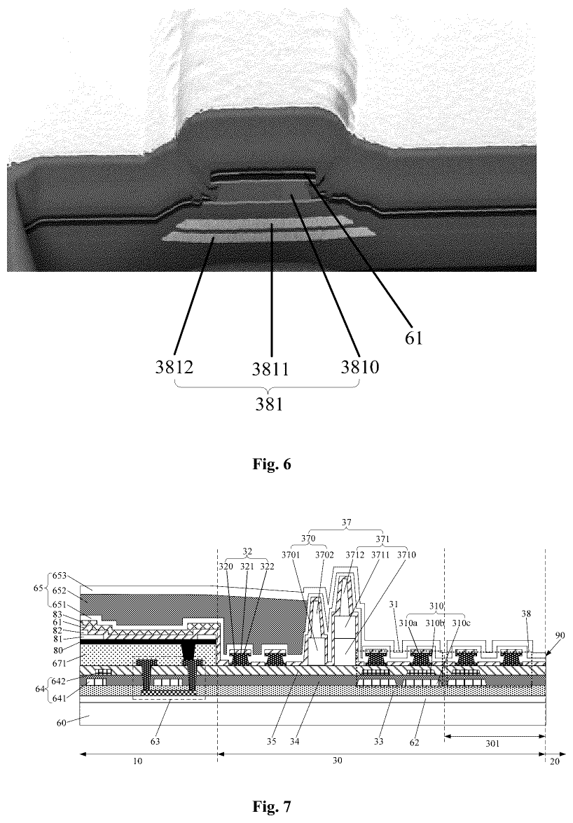

As shown in FIGS. 7 and 11, in some embodiments, the plurality of first barrier members 381 are divided into a first portion of the first barrier members 381 and a second portion of the first barrier members 381, the first portion of the first barrier members 381 being located between the second portion of the first barrier members 381 and the plurality of second barrier members 310.

The first portion of the first barrier members 381 includes the second barrier pattern 3811 and a third barrier pattern 3812.

The second portion of the first barrier members 381 does not include the second barrier pattern 3811 and the third barrier pattern 3812.

Illustratively, the first portion of the first barrier members 381 includes at least one of the first barrier members 381 and the second portion of the first barrier members 381 includes at least one of the first barrier members 381.

The above-mentioned arrangement that the first part of the first barrier members 381 includes the second barrier pattern 3811 and the third barrier pattern 3812, and the second part of the first barrier members 381 does not include the second barrier pattern 3811 and the third barrier pattern 3812, not only ensures the adhesion of the first part of the encapsulation structure 65 to the film layer below the encapsulation structure 65, but also reduces the manufacturing cost of the display substrate.

As shown in FIGS. 4, 7-12, in some embodiments, the second barrier member 310 is structurally identical to the first portion of the first barrier members 381.

Illustratively, as shown in FIGS. 4 and 7 to 12, the second barrier member 310 includes a first pattern 310a having the same structure as the first barrier pattern 3810 and capable of being formed in the same patterning process, a second pattern 310b having the same structure as the second barrier pattern 3811 and capable of being formed in the same patterning process, and a third pattern 310c having the same structure as the third barrier pattern 3812 and capable of being formed in the same patterning process.

Illustratively, the second gate insulating layer 34 is located between the second pattern 310b and the third pattern 310c, and the inter-layer insulating layer 35 is located between the first pattern 310a and the second pattern 310b.

The above-mentioned structure of the second barrier member 310 is the same as that of the first part of the first barrier member 381, not only enabling the second barrier member 310 to space adjacent inorganic film layers, avoiding the contact stacking of multiple inorganic film layers, and blocking the path of the crack extending to the first pixel region 10. Furthermore, the light-emitting functional layer 61 can be blocked to prevent intrusion of moisture and oxygen into the first pixel region 10 by using the light-emitting functional layer 61 as a transmission path.

As shown in FIGS. 4 and 7-12, in some embodiments, the display substrate further includes:
a retaining wall structure 37, where the retaining wall structure 37 is arranged on the isolation region 30, and the orthographic projection of the fracture barrier structure 31 on the base 60 of the display substrate is located between the orthographic projection of the retaining wall structure 37 on the base 60 and the orthographic projection of the peel-off barrier structure 38 on the base 60; and
the encapsulation structure 65 extending from the first pixel region 10 to the isolation region 30, where the encapsulation structure 65 includes a first inorganic encapsulation layer 651, an organic encapsulation layer 652 and a second inorganic encapsulation layer 653 which are stacked in sequence in a direction away from the base 60; the first inorganic encapsulation layer 651 and the second inorganic encapsulation layer both include the first portion; the organic encapsulation layer 652 is located on the side of the retaining wall structure 37 away from the open pore region 20.

Illustratively, the retaining wall structure 37 is disposed around the open pore region 20. Illustratively, the orthographic projection of the retaining wall structure 37 on the base 60 of the display substrate is between the orthographic projection of the fracture barrier structure 31 on the base 60 of the display substrate and the first pixel region 10.

Illustratively, the encapsulation structure 65 includes a first inorganic encapsulation layer 651, an organic encapsulation layer 652 and a second inorganic encapsulation layer 653 which are stacked in sequence in a direction away from the base 60; the first inorganic encapsulating layer 651 and the second inorganic encapsulating layer 653 may both be fabricated by chemical vapor deposition. The organic encapsulation layer 652 may be fabricated by using an inkjet printing process.

Illustratively, the first inorganic encapsulation layer 651 and the second inorganic encapsulation layer can each completely cover all the structures of the display substrate disposed in the first pixel region 10, and can each completely cover all the structures of the display substrate located in the isolation region 30. Illustratively, the first inorganic encapsulation layer 651 and the second inorganic encapsulation layer each include the first portion and are each capable of completely covering the retaining wall structure 37, the fracture barrier structure 31, and the peel-off barrier structure 38, the first inorganic encapsulation layer 651 and the second inorganic encapsulation layer each being capable of extending to a boundary of the open pore region 20 and the open pore region 20.

Illustratively, the organic encapsulation layer 652 can completely cover the entire structure of the display substrate disposed in the first pixel region 10; the organic encapsulation layer 652 can also cover all structures disposed in the isolation region 30 on the side of the retaining wall structure 37 facing the first pixel region 10.

The retaining wall structure 37 is capable of blocking the overflow of the organic encapsulating material used to fabricate the organic encapsulating layer 652 during the fabrication of the organic encapsulating layer 652, thereby confining the organic encapsulating material to the side of the retaining wall structure 37 facing away from the open pore region 20.

As shown in FIGS. 4 and 7-12, in some embodiments, the retaining wall structure 37 includes a first retaining wall 370 and a second retaining wall 371, the first retaining wall 370 and the second retaining wall 371 are sequentially arranged in a direction near the open pore region 20, and a height of the first retaining wall 370 is lower than a height of the second retaining wall 371 in a direction perpendicular to the base 60.

In particular, the specific structure of the barrier structure is various, and illustratively, the retaining wall structure 37 includes a plurality of retaining walls sequentially arranged in a direction close to the open pore region 20, and the height of the plurality of retaining walls sequentially increases in a direction perpendicular to the base 60 in the direction close to the open pore region 20.

Illustratively, the first retaining wall 370 and the second retaining wall 371 both surround the open pore region 20.

The above-mentioned arrangement of the retaining wall structure 37 including the first retaining wall 370 and the second retaining wall 371 not only achieves effective blocking of the organic encapsulation layer 652, but also makes the retaining wall structure 37 occupy a smaller layout space.

As shown in FIGS. 4 and 7-12, in some embodiments, the display substrate further includes:
a planarization layer, a pixel definition layer 81 and a spacer layer 82 which are sequentially stacked and arranged in a direction away from the base 60, where the planarization layer, the pixel definition layer 81 and the spacer layer 82 are all located in the first pixel region 10;
the first retaining wall 370 including a first retaining wall pattern 3701 and a second retaining wall pattern 3702 which are stacked in sequence in a direction away from the base 60; where
the first retaining wall pattern 3701 and the pixel definition layer 81 are arranged on the same layer and in the same material, and the second retaining wall pattern 3702 and the spacer layer 82 are arranged on the same layer and in the same material; or the first retaining wall pattern 3701 and the planarization layer are arranged on the same layer and in the same material, and the second retaining wall pattern 3702 and the pixel defining layer 81 are arranged on the same layer and in the same material; and
the second retaining wall 371 includes a third retaining wall pattern 3710, a fourth retaining wall pattern 3711 and a fifth retaining wall pattern 3712 which are stacked in sequence in a direction away from the base 60; the third retaining wall pattern 3710 and the planarization layer are arranged on the same layer and in the same material, the fourth retaining wall pattern 3711 and the pixel defining layer 81 are arranged on the same layer and in the same material, and the fifth retaining wall pattern 3712 and the spacer layer 82 are arranged on the same layer and in the same material.

Illustratively, the planarization layer includes a first planarization layer 671. Illustratively, the planarization layer includes a second planarization layer 672.

Illustratively, the planarization layer includes a first planarization layer 671 and a second planarization layer 672 stacked in sequence in a direction away from the base 60 with a second source drain metal layer 66 disposed therebetween.

Illustratively, at least a portion of the planarization layer, at least a portion of the pixel definition layer 81, and at least a portion of the spacer layer 82 are all located in the first pixel region 10.

Illustratively, the first retaining wall pattern 3701 and the first planarization layer 671 are arranged on the same layer and in the same material; alternatively, the first retaining wall pattern 3701 and the second planarization layer 672 are disposed on the same layer and in the same material.

Illustratively, the third retaining wall pattern 3710 and the first planarization layer 671 are provided on the same layer and in the same material; alternatively, the third retaining wall pattern 3710 and the second planarization layer 672 are disposed on the same layer and in the same material.

The above-mentioned forming the first retaining wall 370 and the second retaining wall 371 in the same process as other film layers included in the display substrate effectively simplifies the manufacturing process of the display substrate and reduces the manufacturing cost of the display substrate.

As shown in FIGS. 4 and 7-12, in some embodiments, the display substrate further includes:
a plurality of inner isolation posts 32, where the plurality of inner isolation posts 32 are arranged on the isolation region 30, the plurality of inner isolation posts 32 are located on one side of the retaining wall structure 37 away from the open pore region 20, the inner isolation posts 32 surround the open pore region 20, the plurality of inner isolation posts 32 are nested and arranged in sequence, and the side surface of the inner isolation posts 32 has a second notch; and
a light-emitting functional layer 61, where the light-emitting functional layer 61 includes a portion located at the first pixel region 10 and a portion of the isolation region 30, and the portion of the light-emitting functional layer 61 located at the isolation region 30 is interrupted at the side of the inner isolation post 32.

Illustratively, the light-emitting functional layer 61 includes at least an organic light-emitting material layer where the organic light-emitting material layer includes an entire organic light-emitting material layer for emitting white light, or an organic light-emitting material layer pattern for emitting colored light such as red light, green light, blue light, etc. Illustratively, the light-emitting functional layer 61 may include, in addition to an organic light-emitting material layer, for example: a common layer of a whole layer structure such as an electron transport layer, an electron injection layer, a hole transport layer and a hole injection layer.

Illustratively, the light emitting functional layer 61 can cover the first pixel region 10 and the isolation region 30 and can extend to the boundary of the open pore region 20.

Illustratively, the inner isolation post 32 has the same structure as the first barrier pattern 3810, and the inner isolation post 32 can be formed in the same patterning process as the first barrier pattern 3810.

The above-mentioned arrangement that the display substrate includes the plurality of inner isolation posts 32 enables the part of the light-emitting functional layer 61 located at the isolation region 30 to be interrupted at the side of the inner isolation posts 32, further avoiding the intrusion of the interior of the display substrate caused by moisture and oxygen penetrating into the interior of the display substrate along the light-emitting functional layer 61 at the cutting line 90 of boundary of the open hole.

As shown in FIGS. 4, 7 and 8, in some embodiments, the display substrate further includes a thin film transistor 63 located at the first pixel region 10, the thin film transistor 63 includes a source drain electrode layer, and the source drain electrode layer includes a first conductive layer, a second conductive layer and the third conductive layer which are stacked in sequence in a direction away from the base 60.

The inner isolation post 32 includes a first isolation pattern 320, a second isolation pattern 321 and a third isolation pattern 322 which are arranged in sequence in a direction away from the base 60, where the first isolation pattern 320 and the first conductive layer are provided on the same layer and in the same material, the second isolation pattern 321 and the second conductive layer are provided on the same layer and in the same material, and the third isolation pattern 322 and the third conductive layer are provided on the same layer and in the same material.

Illustratively, the first pixel region 10 includes a sub-pixel driving circuit, where the sub-pixel driving circuit includes the thin film transistor 63, a source drain electrode layer of the thin film transistor 63 is made of a first source drain metal layer, and the source drain electrode layer includes a source electrode and a drain electrode.

Illustratively, the first conductive layer and the third conductive layer are made of metal Ti, and the second conductive layer is made of metal Al. The source drain electrode layer and the first barrier pattern 3810 are formed in the same manner and will not be described in detail herein.

Illustratively, the inner isolation post 32 includes a first isolation pattern 320, a second isolation pattern 321, and a third isolation pattern 322 stacked on another in a direction away from the base 60, a boundary of the first isolation pattern 320 and a boundary of the third isolation pattern 322 each exceeding a boundary of the second isolation pattern 321 in a direction parallel to the base 60, and the second notch is formed between the first isolation pattern 320 and the third isolation pattern 322.

The source drain electrode layer and the inner isolation column 32 can be formed simultaneously in the same patterning process, which effectively simplifies the manufacturing process of the display substrate and reduces the manufacturing cost of the display substrate.

As shown in FIGS. 9-12, in some embodiments, the display substrate further includes a second source drain metal layer 66 located at the first pixel region 10, and the second source drain metal layer 66 includes a fourth conductive layer, a fifth conductive layer and the sixth conductive layer which are stacked in sequence in a direction away from the base 60.

The first isolation pattern 320 and the fourth conductive layer are disposed on the same layer and in the same material, the second isolation pattern 321 and the fifth conductive layer are disposed on the same layer and in the same material, and the third isolation pattern 322 and the sixth conductive layer are disposed on the same layer and in the same material.

Illustratively, the fourth conductive layer and the sixth conductive layer are made of metal Ti, and the fifth conductive layer is made of metal Al.

The second source drain metal layer 66 and the inner isolation post 32 can be formed simultaneously in the same patterning process, which effectively simplifies the manufacturing process of the display substrate and reduces the manufacturing cost of the display substrate.

Embodiments of the present disclosure also provide a display device including the display substrate provided by the above embodiments.

Owing to the display substrate provided by above-described embodiments, by providing the fracture barrier structure 31 in the isolation region 30, cracks located in the vicinity of the open pore region 20 are effectively blocked from extending into the first pixel region 10. At the same time, by providing the peel-off barrier structure 38 at the reserved cutting transition region 301, the adhesion between the first portion and the underlying film layer is enhanced, the risk of peeling off the first portion from the display substrate is reduced, and the yield of reliability of the display substrate is ensured.

Therefore, the display device provided by the embodiments of the present disclosure has the above-mentioned advantageous effects also when including the above-mentioned display substrate, and the description thereof will not be repeated here.

It needs to be noted that the display device may be: any product or component with display function such as television, display, digital photo frame, mobile phone and tablet computer.

Embodiments of the present disclosure also provides a method for manufacturing a display substrate, the manufacturing method being used for manufacturing the display substrate provided in above-mentioned embodiments, the display substrate including a display region, the display region including an open pore region 20, a first pixel region 10 and an isolation region 30; the isolation region 30 being located between the first pixel region 10 and the open pore region 20, the isolation region 30 surrounding the open pore region 20, and a boundary line between the open pore region 20 and the isolation region 30 being a cutting line 90; the method for manufacturing the display substrate including:
fabricating a fracture barrier structure 31, the fracture barrier structure 31 being located at the isolation region 30;
fabricating a peel-off barrier structure 38, the peel-off barrier structure 38 being located at the reserved cutting transition area 301 and the sacrificial cutting transition area 302; the distance L between the side of the peel-off barrier structure closest to the open pore region and the cutting line being such that: 0 μm≤L≤30 μm;
fabricating an encapsulation structure 65, a first portion of the encapsulation structure 65 being located on a side of the peel-off barrier structure 38 facing away from the base 60; the peel-off barrier structure 38 making the surface of the display substrate in contact with the first portion uneven.

The steps of forming the open pore region 20 and the isolation region 30 include: the display substrate being cut along the cutting line 90, the cutting line 90 being a boundary line between the reserved cutting transition region 301 and the sacrificial cutting transition region 302, and the whole structure surrounded by the cutting line 90 being removed to form the open pore region 20.

Illustratively, the display substrate has a display region and a peripheral region surrounding the display region, the display region include a first pixel region 10, an open pore region 20, and an isolation region 30 between the first pixel region 10 and the open pore region 20. The isolation region 30 is arranged around the open pore region 20, and the first pixel region 10 is arranged around the isolation region 30.

Illustratively, the display substrate includes a rectangular display region, the open pore region 20 is located at the upper left corner, the upper middle corner or the upper right corner of the rectangular display region, and the specific location and shape of the open pore region 20 are not particularly required. Illustratively, the shape of the open pore region 20 includes: circular or rectangular shapes.

The isolation region 30 is provided with an inorganic layer structure located on the base 60; the inorganic layer structure includes a plurality of inorganic film layers arranged in a stacked manner; each inorganic film layer is formed as an integral structure with a corresponding inorganic film layer (such as a first gate insulation layer 33, a second gate insulation layer 34, an inter-layer insulation layer 35, etc.) in the first pixel region 10; and the inorganic film layer can function as an insulation layer in the first pixel region 10. The inorganic film layer has poor flexibility, and when the opening hole region 20 is cut and formed, the inorganic film layer at the cutting line 90 is easy to have a brittle fracture, and the crack easily takes the inorganic film layer as a channel and further extends to the first pixel region 10, so as to affect the yield of the display substrate.

Illustratively, the fracture barrier structure 31 surrounds the open pore region 20. The fracture barrier structure 31 is capable of spacing adjacent inorganic film layers so that contact stacking of multiple inorganic film layers can be avoided, blocking the path of the crack extending to the first pixel region 10.

Illustratively, the reserved cutting transition region 301 is disposed around the open pore region 20. Notably, the display substrate includes a cutting transition region prior to forming the open pore region 20, the cutting transition region including a reserved cutting transition region 301 and a sacrificial cutting transition region 302, the reserved cutting transition region 301 having the same structure as the sacrificial cutting transition region 302, the reserved cutting transition region 301 and the sacrificial cutting transition region 302 both being formed with the peel-off barrier structure 38.

The reserved cutting transition region 301 and the sacrificial cutting transition region 302 are divided by a cutting line 90 along which a structure included by the reserved cutting transition region 301 remains and a structure included by the sacrificial cutting transition region 302 is removed to form the open pore region 20. Since the specific position of the cutting line 90 is selected at the cutting transition region, and the cutting transition region is provided with the peel-off barrier structure 38 as a whole, no matter where the cutting line 90 is specifically selected at the cutting transition region, the peel-off barrier structure 38 can be ensured to be provided on the reserved cutting transition region 301 after cutting, and the peel-off barrier structure 38 can make the surface of the display substrate in contact with the first portion uneven, increasing the contact area between the first portion and the underlying film layer in contact therewith; the adhesion between the first portion and the underlying film layer is thus well enhanced, reducing the risk of peeling off the first portion from the display substrate.

At least a portion of the encapsulation structure 65 can cover the entire region of the display substrate, and the encapsulation structure 65 can effectively block the intrusion of external moisture and oxygen into the interior of the display substrate, which is advantageous for extending the service life of the display substrate.

In a display substrate fabricated by using a fabrication method provided by an embodiment of the present disclosure, by providing the fracture barrier structure 31 at the isolation region 30, a crack located near the open pore region 20 is effectively blocked from extending into the first pixel region 10. At the same time, by providing the peel-off barrier structure 38 at the reserved cutting transition region 301, the adhesion between the first portion and the underlying film layer is enhanced, the risk of peeling off the first portion from the display substrate is reduced, and the yield of reliability of the display substrate is ensured.

It needs to be noted that the “same layer” of the embodiments of the present disclosure may refer to a film layer on the same structural layer. Or, for example, the film layer on the same layer may be a layer structure formed by forming a film layer for forming a specific pattern by using the same film forming process and then patterning the film layer by one patterning process by using the same mask plate. Depending on the particular pattern, a single patterning process may include multiple exposure, development, or etching processes, and the particular pattern in the resulting layer structure may or may not be continuous. The particular patterns may also be at different heights or have different thicknesses.

In the various methods and embodiments of the present disclosure, the serial number of each step cannot be used to define the order of each step, and for a person of ordinary skill in the art, without involving any inventive effort, changes in the order of each step are also within the scope of the present disclosure.

It needs to be noted that the various embodiments described herein are described in a progressive manner with reference to the same or similar parts throughout the various embodiments, with each embodiment focusing on differences from the other embodiments. In particular, the methods and embodiments are described more simply because they are substantially similar to the product embodiments, with reference to the description of the product embodiments.

Unless defined otherwise, technical or scientific terms used in this disclosure shall have the ordinary meaning as understood by one of ordinary skill in the art to which this disclosure belongs. The use of “first”, “second”, and the like in this disclosure does not denote any order, quantity, or importance, but rather is used to distinguish one element from another. The word “comprise” or “include”, and the like, means that the presence of an element or item preceding the word covers the presence of the element or item listed after the word and equivalents thereof, but does not exclude other elements or items. The terms “connect”, “coupled”, or “link”, and the like, are not limited to physical or mechanical connections, but may include electrical connections, whether direct or indirect. The terms “upper”, “lower”, “left”, “right” and the like are used only to indicate relative positional relationships that may change accordingly when the absolute position of the described object changes.

It will be understood that when an element such as a layer, film, region or substrate is referred to as being “on” or “under” another element, it can be “directly on” or “directly under” the other element or intermediate elements may be present.

In the description of the embodiments above, particular features, structures, materials, or characteristics may be combined in any suitable manner in any one or more embodiments or examples.

While the foregoing is directed to embodiments of the present disclosure, other and further embodiments of the disclosure may be devised without departing from the basic scope thereof, and the scope thereof is determined by the claims that follow. Accordingly, the protection sought herein is as set forth in the claims below.

1. A display substrate comprising a display region, wherein the display region includes an open pore region, a first pixel region and an isolation region; the isolation region is located between the first pixel region and the open pore region, the isolation region surrounds the open pore region, and a boundary line between the open pore region and the isolation region is a cutting line; and the display substrate further comprises:
a fracture barrier structure located at the isolation region, the isolation region comprising a reserved cutting transition region located between the fracture barrier structure and the open pore region;
a peel-off barrier structure located at the reserved cutting transition region; the distance L between the side of the peel-off barrier structure closest to the open pore region and the cutting line is such that: 0 μm≤L≤30 μm; and
an encapsulation structure, a first part of the encapsulation structure being located on a side of the peel-off barrier structure facing away from the base of the display substrate; the peel-off barrier structure makes the surface of the display substrate in contact with the first portion uneven.

2. The display substrate according to claim 1, wherein the peel-off barrier structure comprises at least one of first barrier members arranged around the open pore region.

3. The display substrate according to claim 2, wherein an orthographic projection of the cutting line on a base of the display substrate at least partially overlaps an orthographic projection of the first barrier member closest to the open pore region on the base; or, the orthographic projection of the cutting line on the base does not overlap the orthographic projection of the first barrier member closest to the open pore region on the base.

4. The display substrate according to claim 2, wherein the peel-off barrier structure comprises a plurality of first barrier members, the plurality of first barrier members being nested in sequence.

5. The display substrate according to claim 4, wherein a distance H2 between adjacent first barrier members satisfies: 10 μm≤H2≤30 μm.

6. The display substrate according to claim 2, wherein the fracture barrier structure comprises a plurality of second barrier members, the second barrier members being arranged around the open pore region, the plurality of second barrier members being nested in sequence.

7. The display substrate according to claim 6, wherein the first barrier members and the second barrier members are arranged equidistantly in a direction parallel to a base of the display substrate; and/or
the arrangement pitch of the first barrier members is larger than the arrangement pitch of the second barrier members in the direction parallel to the base of the display substrate.

8. The display substrate according to claim 6, wherein the first barrier member comprises:
a first barrier pattern, a side of the first barrier pattern having a first notch.

9. The display substrate according to claim 8, wherein the first barrier pattern comprises a first sub-pattern, a second sub-pattern and a third sub-pattern stacked in sequence in a direction away from a base of the display substrate, boundaries of the first sub-pattern and the third sub-pattern each exceed boundaries of the second sub-pattern in a direction parallel to the base, and the first notch is formed between the first sub-pattern and the third sub-pattern.

10. The display substrate according to claim 9, wherein the display substrate further comprises a thin film transistor located at the first pixel region, the thin film transistor comprises a source drain electrode layer, and the source drain electrode layer comprises a first conductive layer, a second conductive layer and a third conductive layer which are stacked in sequence in a direction away from the base; the first sub-pattern and the first conductive layer are arranged on the same layer and in the same material, the second sub-pattern and the second conductive layer are arranged on the same layer and in the same material, and the third sub-pattern and the third conductive layer are arranged on the same layer and in the same material; or,
the display substrate further comprises a second source drain metal layer located at the first pixel region, and the second source drain metal layer comprises a fourth conductive layer, a fifth conductive layer and a sixth conductive layer which are stacked in sequence along the direction away from the base; the first sub-pattern and the fourth conductive layer are arranged on the same layer and in the same material, the second sub-pattern and the fifth conductive layer are arranged on the same layer and in the same material, and the third sub-pattern and the sixth conductive layer are arranged on the same layer and in the same material.

11. The display substrate according to claim 9, wherein at least part of the first barrier member further comprises: a second barrier pattern and a third barrier pattern, the second barrier pattern being located between the first barrier pattern and a base of the display substrate, and the third barrier pattern being located between the second barrier pattern and the base.

12. The display substrate according to claim 11, wherein, in the same first barrier member, the orthographic projection of the second barrier pattern on the base is located inside the orthographic projection of the third barrier pattern on the base.

13. The display substrate according to claim 11, wherein the display substrate further comprises a sub-pixel driving circuit located at the first pixel region, the sub-pixel driving circuit comprising a capacitance structure, the capacitance structure comprising a first plate and a second plate arranged opposite to each other, and the first plate being located between the second plate and the base of the display substrate; and
the second barrier pattern and the second plate are arranged on the same layer and in the same material; and/or the third barrier pattern and the first plate are arranged on the same layer and in the same material.

14. The display substrate according to claim 11, wherein the plurality of first barrier members are divided into a first portion of the first barrier members and a second portion of the first barrier members, the first portion of the first barrier members being located between the second portion of the first barrier members and the plurality of second barrier members;
the first portion of the first barrier members comprises the second barrier pattern and a third barrier pattern;
the second portion of the first barrier members does not comprise the second and third barrier patterns; and
the second barrier member has the same structure as the first portion of the first barrier members.

15. The display substrate according to claim 1, wherein the display substrate further comprises:
a retaining wall structure, the retaining wall structure being arranged on the isolation region, the orthographic projection of the fracture barrier structure on the base of the display substrate being located between the orthographic projection of the retaining wall structure on the base and the orthographic projection of the peel-off barrier structure on the base;
the encapsulation structure extending from the first pixel region to the isolation region, and the encapsulation structure comprising a first inorganic encapsulation layer, an organic encapsulation layer and a second inorganic encapsulation layer which are stacked in sequence in a direction away from the base; the first inorganic encapsulation layer and the second inorganic encapsulation layer both comprising the first portion; the organic encapsulation layer being located on a side of the retaining wall structure away from the open pore region; and
the retaining wall structure comprising a first retaining wall and a second retaining wall, wherein the first retaining wall and the second retaining wall are sequentially arranged in a direction close to the open pore region, and a height of the first retaining wall being lower than a height of the second retaining wall in a direction perpendicular to the base.

16. The display substrate according to claim 15, wherein the display substrate further comprises:
a planarization layer, a pixel definition layer and a spacer layer which are sequentially stacked and arranged in a direction away from the base, wherein the planarization layer, the pixel definition layer and the spacer layer are all located in the first pixel region;
the first retaining wall comprising a first retaining wall pattern and a second retaining wall pattern which are stacked in sequence in a direction away from the base;
the first retaining wall pattern and the pixel definition layer being arranged on the same layer and in the same material, and the second retaining wall pattern and the spacer layer being arranged on the same layer and in the same material; or the first retaining wall pattern and the planarization layer being arranged on the same layer and in the same material, and the second retaining wall pattern and the pixel defining layer being arranged on the same layer and in the same material; and
the second retaining wall comprising a third retaining wall pattern, a fourth retaining wall pattern and a fifth retaining wall pattern which are stacked in sequence in a direction away from the base; the third retaining wall pattern and the planarization layer being arranged on the same layer and in the same material, the fourth retaining wall pattern and the pixel definition layer being arranged on the same layer and in the same material, and the fifth retaining wall pattern and the spacer layer being arranged on the same layer and in the same material.

17. The display substrate according to claim 15, wherein the display substrate further comprises:
a plurality of inner isolation posts, wherein the plurality of inner isolation posts are arranged at the isolation region, the plurality of inner isolation posts are located at one side of the retaining wall structure away from the open pore region, the inner isolation posts surround the open pore region, the plurality of inner isolation posts are nested and arranged in sequence, and a side surface of the inner isolation posts has a second notch; and
a light-emitting functional layer, wherein the light-emitting functional layer comprises a portion located at the first pixel region and a portion of the isolation region, and the portion of the light-emitting functional layer located at the isolation region is interrupted at the side of the inner isolation posts.

18. The display substrate according to claim 17, wherein the display substrate further comprises a thin film transistor located in the first pixel region, the thin film transistor comprises a source drain electrode layer, and the source drain electrode layer comprises a first conductive layer, a second conductive layer and the third conductive layer which are stacked in sequence in a direction away from the base; the inner isolation post comprises a first isolation pattern, a second isolation pattern and a third isolation pattern which are stacked and arranged in sequence along a direction away from the base, the first isolation pattern and the first conductive layer are arranged on the same layer and in the same material, the second isolation pattern and the second conductive layer are arranged on the same layer and in the same material, and the third isolation pattern and the third conductive layer are arranged on the same layer and in the same material; or,
the display substrate further comprises a second source drain metal layer located at the first pixel region, and the second source drain metal layer comprises a fourth conductive layer, a fifth conductive layer and a sixth conductive layer which are stacked in sequence along the direction away from the base; the first isolation pattern and the fourth conductive layer are arranged on the same layer and in the same material, the second isolation pattern and fifth conductive layer are arranged on the same layer and in the same material, and the third isolation pattern and the sixth conductive layer are arranged on the same layer and in the same material.

19. A display device comprising the display substrate according to claim 1.

20. A method for manufacturing a display substrate, wherein the display substrate comprises a display region, and the display region comprises an open pore region, a first pixel region and an isolation region; the isolation region is located between the first pixel region and the open pore region, the isolation region surrounds the open pore region, and a boundary line between the open pore region and the isolation region is a cutting line; the method for manufacturing the display substrate comprising:
fabricating a fracture barrier structure located in the isolation region;
fabricating a peel-off barrier structure, the peel-off barrier structure being located at the reserved cutting transition region and the sacrificial cutting transition region; the distance L between the side of the peel-off barrier structure closest to the open pore region and the cutting line is such that: 0 μm≤L≤30 μm;
fabricating an encapsulation structure, a first portion of the encapsulation structure being located on a side of the peel-off barrier structure facing away from the base; the peel-off barrier structure makes the surface of the display substrate in contact with the first portion uneven; and
the step of forming the open pore region and the isolation region comprises: cutting the display substrate along the cutting line, the cutting line being a boundary line between the reserved cutting transition region and the sacrificial cutting transition region, and removing all the structures surrounded by the cutting line to form the open pore region.
